(19) United States
(12) Patent Application Publication
(10) Pub. No.: US 2012/0308807 A1
(43) Pub. Date: Dec. 6, 2012

(54) Porous Materials

(75) Inventor: Geoffrey A. Edwards, Pt. Arkwrite (AU)

(73) Assignee: Nano-Nouvelle Pty Ltd, Marcoola (AU)

(21) Appl. No.: 13/509,180

(22) PCT Filed: Nov. 11, 2010
(86) PCT No.: PCT/AU2010/001511

§ 371 Date: Aug. 23, 2012

(30) Foreign Application Priority Data
Nov. 11, 2009 (AU) 2009905532
Mar. 11, 2010 (AU) 2010901022
Jun. 8, 2010 (AU) 2010902509

(51) Int. Cl. H01B 1/00; B05D 5/12; B29C 41/42; B32B 3/26; C23C 16/44; B82Y 40/00; B82Y 30/00

(52) U.S. Cl. 428/319.1; 428/304.4; 427/243; 264/334; 252/500; 977/755; 977/890

(57) ABSTRACT

A porous membrane material comprising a porous membrane substrate coated with a thin, uniform coating of a different material. The membrane material can have high electrical conductivity. The membrane material can exhibit a very high ratio of electrical conductivity to thermal conductivity. The porous membrane substrate may be removed to form the membrane.

### FIELD OF THE INVENTION

The present invention relates to novel porous materials. In one aspect, the invention relates to porous membrane materials where specific functionalities are provided by a thin, uniform coating that is applied to an existing porous membrane material.

### BACKGROUND TO THE INVENTION

Porous materials, and porous membrane materials, have wide ranging application. Materials with controlled pore structures are useful in, for example, filters for separation, water purification, air treatment, catalysis, and removal of heavy metal or biological contaminants. Materials with controllable pore sizes and conductivity are useful for applications such as batteries, supercapacitors, fuel cells and gas sensors. Pores in the nanometre size range are useful for separation processes and reactions involving biologically active molecules.

The pore structure can be critical to the performance of the porous material and/or membrane. For example, the function of filtration membranes is often to filter particles of a specific size. Usually the maximum size of particle that can pass through the membrane is specified. Thus tight control of pore structure is necessary to enable correct specification of this particle size. It may also be important to have a pore structure that achieves the required maximum particle size whilst exhibiting good permeability and that provides adequate mechanical strength.

Pore structures are critical to fluid flow through membranes. A common desire is to maximise the permeability of a membrane, which leads to lower pressure drops and therefore less energy is required to move fluid through the membrane. The permeability is a strong function of the pore structure, hence controlled and advanced pore structures are desirable.

Conducting membranes are also desired in many applications. In particular, combinations of conductivity and controlled pore structure for managing fluid flow are desired in applications such as dye-sensitised solar cells, batteries, gas sensors, fuel cells, super-capacitors, electrolysers, photo-electrodes and some water treatment and air treatment applications. For example, many gas sensors work by using a material that changes conductivity with exposure to gas. The porous nature of the gas sensor may affect its operation by controlling how much material is exposed to the gas, and how quickly this exposure occurs. Dye-sensitised solar cells, fuel cells and batteries also require conducting porous electrodes. The porous nature of these electrodes can also be critical, as the pore structure controls movement of fluids and/or ionic species in solution. In some filtration and water treatment applications, it is important to have a conducting membrane so that a voltage may be applied to the membrane. Permeability is again critical in terms of the pressure drop associated with flow, and associated energy requirements.

In some applications a high ratio of electrical conductivity to thermal conductivity is desired. In other words, materials with high electrical conductivity and low thermal conductivity are needed. Materials with high electrical conductivity usually exhibit high thermal conductivity. The requirement of high ratio of electrical to thermal conductivity therefore presents a significant challenge. An example of such an application is thermoelectric materials.

The field of membranes is vast and many other functionalities are required in different applications

Current membranes can be categorised into two main groups: polymer-based membranes and ceramic membranes. Whilst there are a wide variety of advanced pore structures and architectures available for polymeric membranes, these membranes are limited by their operating temperatures and resistance to certain environments. In addition, inorganic materials such as ceramics can provide functionalities that cannot be provided by polymers. For example, in many applications it would be advantageous to have conducting membranes.

Ceramic membranes exist but are much more limited in terms of available pore structures and architectures.

Polymeric membranes include filter membranes. These may be made from a variety of polymers, including cellulose, cellulose nitrate, cellulose acetate, mixed cellulose esters, nylon, PTFE (Teflon), polyether sulfones (PES), polyamides, vinyl polymers and polycarbonates. The membranes are available in a range of pore types and sizes. Typically the pore sizes are specified by the maximum particle size that can pass through the membrane. For example, a particular membrane type may be available in specified pore sizes from 0.1 μm to 10 μm. Track-etched filter membranes (typically polycarbonates) have straight cylindrical pores. However many membranes have much more complex and irregular pore structures. These include the cellulose-based filter membranes, and some nylon, PTFE and PES filter membranes.

Membranes can be made with a wide range of thicknesses, for example a few micrometres thick up to hundreds of micrometres thick or even greater into the millimetre range.

It is an object of the present invention to provide materials that significantly expand the available combinations of pore structure and functionality in membranes.

The present inventors have found that it is possible to provide desired functionalities by applying thin, uniform coatings to existing porous materials or membranes. In this way, it is possible to combine the pore structures provided by polymer-based membrane materials with functionalities provided by inorganic materials. This functionality can be added while essentially preserving, or at least altering in a controlled manner, the pore characteristics of the existing materials.

Unusual combinations of controlled pore structures and properties such as conductivity, resistance to environment and electrical conductivity to thermal conductivity ratio may be achieved by applying a thin coating of uniform thickness to an existing porous membrane. Since the coating may be very thin, the effect on pore structures may be minimised. Since the coating thickness is very controlled, the effect on pore structures may be controlled. Also the volume fraction of coating may be controlled.

The inventors have surprisingly found that enhanced properties may be obtained by using very thin coatings and low volume fractions of solid. This is important for commercial applications.

The inventors have also surprisingly found that these enhanced properties may be achieved by coating a porous scaffold then removing the scaffold whilst maintaining reasonable properties or even enhancing properties. This removal may be achieved without excessive shrinkage in the thickness direction.

### DESCRIPTION OF THE INVENTION

The inventors have surprisingly found that porous membrane materials, including polymeric filter membranes, may be coated with a uniform, thin inorganic coating which can lead to unusual features. The coating essentially preserves the original pore structure of the material. Since the coating is uniform and the thickness may be tightly controlled, the effect of the coating on the pore characteristics of the membrane, together with their associated important properties such as permeability, can be minimised or altered in a controlled manner.

In one aspect, the present invention provides a porous material, such as a porous membrane material comprising a porous substrate coated with a thin, uniform coating of a different material. The porous substrate may be a porous membrane substrate.

In one embodiment, the porous membrane substrate comprises a filter membrane.

In one embodiment, the porous material is formed by coating a porous substrate and treating the coated material to remove the substrate and leave a porous material.

In one embodiment, the porous membrane material is formed by coating a porous membrane substrate and treating the coated material to remove the substrate and leave a porous membrane.

In one embodiment, the coating imparts high electrical conductivity to the porous material. One way of describing conductivity in porous solids is to use an ‘equivalent solid’ conductivity. For example, if the material has a volume fraction of solid of only 20%, and the measured conductivity is x, the ‘equivalent solid’ conductivity would be 5 times x. Similarly, if the material has a volume fraction of solid of 50%, and the measured conductivity is y, the ‘equivalent solid’ conductivity would be 2 times y. This way of comparison is useful for comparing the quality of solids in structures with different volume fraction of solids. For example, comparison of the quality of the solid formed by making coatings of different thicknesses in the present invention.

In the case where the porous material is formed by a coating of material on an inert porous scaffold, it is the volume fraction of the coating material that is relevant in calculating the equivalent solid conductivity.

The concept of equivalent solid conductivity can also be applied to thermal conductivity.

In the present invention, the equivalent conductivity of the porous material may compare favourably to conductivities obtained by depositing thin films of solid materials of similar composition onto planar substrates, in particular where the thin film is of similar thickness to the coatings deposited on the porous substrates. By way of illustration, if we coat a porous substrate with a 80 nm thick coating of Al-doped ZnO, a comparative thin film materials would be a solid layer of Al-doped ZnO, 80 nm thick, deposited onto a flat, solid substrate. This is surprising given the tortuosity of the porous substrates, the possibilities of dead ends, and the difficulties of depositing quality material into such structures. Also surprisingly, this conductivity is retained or even enhanced following removal of the substrate, eg. by heat treatment. For example, the equivalent conductivities of the materials of the present invention may be ˜¼ that obtained for thin films of similar composition and thickness deposited on solid substrates, or it may be ˜½, or it may be ˜comparable to such values, or even superior. Importantly this may be achieved with low volume fractions of solid, eg. less than 50%, or less than 40%, or less than 30%, or less than 20%.

The equivalent conductivities also compare favourably with solid (bulk) versions of materials with similar compositions. By bulk version of the materials of the present invention, we mean a solid piece of material that is of similar composition to the solid material that is present in the porous materials of the present invention. In the case where the materials of the present invention comprise a coating of material that is put onto an essentially inert scaffold/porous substrate, the relevant bulk material has similar composition to the coating. For example, if Al-doped ZnO is coated onto a porous polymer substrate according to the present invention, then an example of a bulk reference material would be a disc of Al-doped ZnO, eg. 20 mm diameter by 5 mm thick. Conductivities of bulk materials are usually better than thin films. For example, the equivalent conductivities of the materials of the present invention may be ˜ 1/50^{th} that obtained for bulk materials of similar composition, or it may be ˜ 1/20^{th}, or ˜ 1/10^{th} or ˜⅕^{th}, or ½ or even comparable to that obtained for bulk materials of similar composition. Again, this is surprising given the tortuosity of the porous materials, the possibility of dead ends and the difficulty of deposition into porous structures.

In some embodiments of the present invention the coating may be a transparent conducting oxide such as doped zinc oxide, doped tin oxide, doped indium oxide, or variants of these. In these embodiments the equivalent solid conductivity of the membrane may range from ˜0.05 S/cm to 1500 S/cm, or 10 S/cm to 1500 S/cm or 100_{.}S/cm to 1500 S/cm.

Surprisingly these conductivities may be achieved with thin coatings, for example from ˜10 nm to ˜200 nm, more suitably from ˜10 nm to ˜100 nm, even more suitably from ˜10 nm to ˜50 nm, most suitably from ˜10 nm to ˜40 nm.˜10 nm, or ˜20 nm thick, or ˜40 nm thick coatings. Also surprisingly, this conductivity can be achieved despite the complex solid structures of many membranes. In particular, the structures potentially represent tortuous paths, have roughness, and could consist of a number of ‘dead ends’. These attributes can potentially significantly reduce conductivity.

Since the thickness of the coating is well controlled, the volume fraction of the coating is also well controlled. Also, the effect on pore structure may be minimised or at least well controlled and defined. For example, if a filter membrane's pore structure is specified as 0.2 μm, this means the largest particle that can pass through is 0.2 μm, or 200 nm. With a conductive coating of controlled thickness 20 nm, the largest particle size that can pass through is then close to 160 nm. It is possible to start with a membrane of a specified particle size, then provide a coating of a defined thickness to achieve a desired specified particle size that can pass through the porous material/membrane.

Also, by combining the surface area and volume fraction of the substrate, with the controlled coating thickness, the volume fraction of coating can be controlled accurately. An example is a filter membrane of surface area 10 m²/g, volume fraction of solid 34%. If a flat surface is assumed, a 40 nm thick coating should lead to a volume fraction of coating of around 20%.

Surprisingly we have also found that membranes of some embodiments of the present invention exhibit a very high ratio of electrical conductivity to thermal conductivity. Materials with high electrical conductivity usually exhibit high thermal conductivity. Materials with high electrical conductivity and low thermal conductivity are, however, in demand in applications such as thermoelectric materials. Without being bound to any particular theory, the present inventors believe that the high ratios of electrical to thermal conductivities in the present materials may be due, at least in part, to phonon impediment at surfaces, probably due to surface roughness. A fine grain size may also be a contributing factor.

This ratio can be significantly higher than for bulk materials of similar composition. For example, the ratio can be 2×higher, or 5×higher, or 10×higher or 20×higher than reported for bulk materials of similar composition.

Accordingly, in another aspect, the present invention provides a porous membrane material having a ratio of electrical conductivity to thermal conductivity at least 2×higher, or 5×higher, or 10×higher or 20×higher than reported for bulk materials of similar composition. Accordingly, in another aspect, the present invention provides a porous membrane material having a ratio of electrical conductivity to thermal conductivity in excess of 10,000 SK/W, for example, from 10,000 to 200,000 SK/W, or from 15,000 to 100,000 SK/W, or from 20,000 to 50,000 SK/W. These figures are for values at room temperature (from ˜15° C. to ˜35° C.). At other temperatures the ratios may change somewhat, therefore different ranges may be relevant at other temperatures.

The inventors have also surprisingly found that the phonon thermal conductivities of the materials of the present invention may be very low. Also, they may be much lower than for bulk materials of similar composition. For example, the phonon thermal conductivity may be less than 0.6 W/m/K, or less than 0.5, or less than 0.3, or less than 0.2. Correspondingly this value may be comparable to the value for bulk materials, or it may be ½, or ¼, or 1/10^{th}, or 1/20^{th}, or 1/50^{th} of these values.

The inventors have found that conductive coatings can also lead to good thermoelectric properties, including high figures of merit, ZT. This is due to the combination of high ratios of electrical to thermal conductivities and reasonable Seebeck coefficients. This ZT may be comparable or higher than ZTs for bulk materials of similar composition. Importantly these ZTs may be obtained with low volume fractions of solid.

Accordingly, in another aspect, the present invention provides a porous material, such as a porous membrane material, having a ZT comparable to that of bulk materials of similar composition, or greater than 1.2×higher than comparable bulk materials, or greater than 2×higher, or greater than 3 times higher, or greater than 5 times higher, or greater than 10×higher. This may be achieved with low volume fractions of solid (v_{f}solid), for example less than 50% v_{f}solid, or less than 40%, or less than 30%, or less than 20% v_{f}solid.

Accordingly, in another aspect, the present invention provides a porous material, such as a porous membrane material having a thermoelectric figure of merit in excess of 0.1, for example, from 0.1 to 5, or from 0.3 to 5, or from 0.3 to 4, or from 0.3 to 3, or from 0.3 to 2, or from 0.3 to 1.5. This may be achieved with low volume fractions of solid, for example less than 50% v_{f}solid, or less than 40%, or less than 30%, or less than 20% v_{f}solid.

Surprisingly, the inventors have found that these properties related to conductivity can be attained using low volume fractions of solid. In prior art, porous ceramics with low volume fractions of solid lead to very low electrical conductivities. Thus the properties of such porous ceramics related to electrical conductivity, e.g. thermoelectric performance, would be expected to be poor. However the present inventors have found that good properties related to electrical conductivity, including thermoelectric performance, may be achieved whilst using low volume fractions of solid. For example the properties may be obtained with a volume fraction of solid less than 50%, or less than 40%, or less than 30%, or less than 20%.

This finding has commercial implications, especially for thermoelectric devices. In thermoelectric devices, attainment of good thermoelectric properties at such low volume fractions can drastically reduce the amount of thermoelectric material required for a device. This is a pressing issue, due both to the cost of the thermoelectric materials and to weight issues, particularly in cars. Using low volume fractions of solid allows use of thinner materials since the thermal resistance, remains sufficiently high to control heat flow. For example, with 20% volume fraction of solid, the thickness may be decreased by a factor of 5 while maintaining thermal resistance. This equates to a reduction in material use of a factor of 25. Further decreases, with respect to normal bulk material, may be gained since the thermal conductivity of the solid part of the materials of the present invention may be reduced compared to the thermal conductivity of normal bulk material.

To address contact issues, it is possible to put a thin layer of solid material on top of our porous membranes, to provide a complete surface for contacting to, for example, metal electrodes.

For conducting coatings, any coating providing suitable conductivity may be used. Examples include oxides such as zinc oxide, indium oxide, indium tin oxide, titanium oxide, tin oxide, gallium oxide, tungsten oxide, cobalt oxides, complex oxides such as strontium titanates and rare earth-type titanates, and perovskite-type oxides and mixtures of these. Also nitrides such as aluminium nitride and gallium nitride, titanium nitride, silicon nitride and mixtures of these. Also metals such as copper, tin, nickel, iron, aluminium, titanium, cobalt, zinc, manganese, silver, gold, and alloys of these. Also thermoelectric materials such as thermoelectric oxides such as zinc-based oxides, cobalt-based oxides, titanium-based oxides including perovskite type oxides, bismuth tellurides, antimony tellurides, lead tellurides, other tellurides and mixed tellurides, Zintl compounds, Huessler materials, skutteridites, silicides, antimonides, and mixtures or compounds based on these, for example so-called TAGS and LAST-type materials. Also other semiconductors such as silicon, germanium, silicon carbides, boron carbides, cadmium telluride, cadmium selenide, indium phosphide, copper indium gallium based semiconductors. It may be appreciated that some oxides and nitrides, and thermoelectric materials, are also considered semiconductor materials. These materials may also be mixed with each other, or with other non-conducting materials. A conductive carbon-based material may also be utilised. This list is not considered exhaustive.

It may be appreciated that many of these materials will require doping to become conductive. Dopants may be intrinsic, which means the doping essentially occurs during the deposition, without intentional addition of specific dopant species. Examples of such intrinsic dopants may be oxygen vacancies, metallic interstitials, hydrogen, oxygen interstitials, metallic vacancies etc. The dopants may also be extrinsic, which means they are specific elements that are added to the material with the specific purpose of doping. A number of different dopants (use of a number of different dopants is often called ‘co-doping’) may be utilised.

In some instances, the material needs to be heat treated or annealed after deposition to activate the dopants. Also, post heat treatment may be used to improve the material, for example by reducing defects, growing grains, activating dopants etc.

The inventors have also found that by using thin, uniform coatings, the resistance of the membranes to environmental conditions such as temperature and chemicals such as solvents, can be improved, whilst maintaining control over the pore characteristics of the membranes. Again, the use of thin, uniform coatings enables this resistance to be achieved whilst essentially preserving the pore structure of the material, or at least altering the pore structure in a controlled manner.

Surprisingly the inventors have found that this resistance to environmental factors such as temperature and chemicals (for example solvents) may be achieved using very thin coatings. For example, materials with enhanced resistance to environmental factors may be achieved with a coating thickness less than 150 nm, or less than 100 nm, or less than 50 nm, or less than 30 nm, or less than 20 nm, or less than 10 nm. It is surprising that such thin coatings can infer increased resistance to environment. Coatings of such thinness, particularly when applied to polymers, would normally be expected to have defects such as pinholes or cracks that can expose the polymer to environmental substances such as air or chemicals. Also, diffusion through such thin layers could be significant.

Achieving property enhancements with such thin layers is important for several reasons:
1) The final product can be made at significantly lower cost. This is both due to lower raw materials costs, and faster throughput through the coating process
2) Thin coatings minimise changes to porosity, i.e. properties can be enhanced with minimal changes to the pore characteristics and associated properties such as permeability.
3) Thin coatings minimise weight, i.e. property enhancement may be achieved without large weight gain. This could have particular relevance if the membrane material is a fabric or textile.

The materials of the present invention may also be post-treated to add additional functionality. For example, nanoparticles of material may be aₚₚlied to the surface to perform specific functions. Also, coatings of other material or materials may be applied to the base structure to impart desired functionalities.

The coating may be applied by any suitable technique. A particularly suitable technique is called atomic layer deposition (ALD).

In other embodiments, the coating may be applied to the surface by various means. For example, further layers may be applied by atomic layer deposition, electrodeposition, electroless deposition, hydrothermal methods, electrophoresis, photocatalytic methods, sol-gel methods, other vapour phase methods such as chemical vapour deposition, physical vapour deposition and close-spaced sublimation. Multiple layers using one or more of these methods may also be used. It may be useful to coat the material such that the composition of the material is not uniform throughout. For example, a coating method may be used that only penetrates partway into the porous material. The coating may also be applied by sequential use of different coating methods.

Atomic layer deposition (ALD) is a deposition method that is known for its ability to apply conformal coatings to variable surfaces, for its accurate control of coating thickness, and for its ability to deposit very thin, pin-hole free coatings. In ALD, precursors are added to a chamber at low pressure and form a layer on the surface. This layer acts as a barrier to further precursor deposition. The precursors are purged, and then a reactant gas is added that reacts with the precursor layer to form a product that is able to accept another monolayer of precursor. Thus, areas that are more exposed to precursor gases receive exactly the same layer coating as areas that take longer to be exposed to precursors. It is known that films deposited by ALD may be ‘pinhole-free’ at much thinner thicknesses compared to other methods. ALD thereby offers control of layer deposition at an unparalleled fine scale. The coatings produced by ALD are commonly ‘conformal’, i.e. they conform to the shape of the substrate.

In one embodiment of the present invention, the original porous substrate may be removed, after application of the coating. The inventors have surprisingly found that high conductivities may still be achieved despite application of the removal process to the material. Removal, for example, by application of heat, may be expected to be detrimental to the solid structure of the material due to forces exerted due to, for example, combustion and/or thermal expansion. Also, the inventors have found that high electrical conductivity to thermal conductivity ratios may still be maintained, even after removal of the original porous substrate. Since this removal creates extra porosity, possibly at a larger scale than the initial porosity, this removal step could potentially increase thermal conductivity by allowing heat transfer via air or other gases. This heat transfer could also or alternatively be via conduction or convection in the gas. The inventors have surprisingly found that the solid part of the original porous substrate may be removed, without greatly increasing the thermal conductivity, or at least without greatly decreasing the ratio of electrical conductivity to thermal conductivity.

In one embodiment of the present invention, the original porous scaffold may be removed whilst maintaining reasonable compressive strength. For example, the material may have a compressive strength of greater than 1 MPa, or greater than 2 MPa, or greater than 10 MPa, or greater than 20 MPa. Surprisingly these compressive strengths may be achieved with low volume fractions of solid, for example less than 50% v_{f} solid, or less than 40%, or less than 30%, or less than 20% v_{f}solid.

In one embodiment of the present invention, the original porous scaffold may be removed without causing significant shrinkage. For example, the thickness of the material after removal of the scaffold may be within 20% of the original thickness, or within 10%, or within 5%, or within 2%.

In another embodiment of the present invention, the coating may be comprised of multiple layers. Said multiple layers may be deposited using one, or more than one, deposition technique.

In another embodiment of the present invention, the coating is comprised of nanolayers of material. The inventors have found that nanolayered materials may be deposited that exhibit good conductivity and good values of electrical to thermal conductivity.

In one embodiment, the coating is applied to the substrate by an ALD process. An ALD process requires the following steps to form a ‘cycle’.
1. Dosing of metal precursor, during which a layer of metal precursor reacts with the surface and is attached to the surface. Additional precursor molecules cannot react with precursor molecules already attached to the surface, so the process is self limiting.
2. Inert gas purge that removes both unreacted precursor molecules, and reaction products from the reaction of precursor molecules with the surface.
3. Dosing of a reactant, which reacts with the metal precursor molecules that are attached on the surface. The surface can then react with another dose of metal precursor.
4. Inert gas purge that removes the reactant.

This cycle may be repeated any number of times in order to build up a coating of controlled thickness.

However, ALD on porous structures, particularly structures with high effective pore aspect ratios (in a cylindrical pore, the aspect ratio is length divided by diameter) has in the past proved problematical. In particular, complex structures with tortuous paths, such as those found in many polymeric filter membranes, can significantly inhibit gaseous flow, thereby creating problems for ALD. Also, deposition on polymeric materials can be difficult due to problems with nucleation.

The inventors have found that these problems can be overcome to provide the materials of the present invention.

In another aspect, the present invention provides a method for forming a porous material comprising providing a porous substrate material and applying a thin uniform coating to the porous structure material.

In some embodiments of the method of the present invention, the porous material is made by applying a thin, uniform coating to a porous substrate material and subsequently removing the porous substrate material. The porous substrate material may be removed, for example, by heat treatment or by chemical treatment. The heat treatment or chemical treatment desirably removes the substrate material without unduly affecting the coating material. Surprisingly it has been found that the polymeric substrate can be, removed without unduly affecting the material in an adverse manner, and in fact the removal process may actually enhance some properties. Removal of such material may normally affect the structural integrity of the structure and/or adversely affect the deposited solid in a chemical way.

In the method of the present invention, the thin uniform coating may be applied using atomic layer deposition (ALD).

In one embodiment of the method of the present invention the atomic layer deposition may be applied in flow through mode.

In another embodiment of the method of the present invention, the porous layer may first be applied to a substrate. The thin coating is then applied to the porous layer, while the porous layer is on the substrate.

In one embodiment of the method of the present invention, the cycle times used in the ALD process are practical. This means that the desired product qualities may be achieved using ALD cycle times that are sufficiently short to be practical. Practical cycle times are necessary for commercially viable manufacturing.

Throughout this specification, where reference is made to a comparison or ratio of properties referenced to the properties of comparable bulk materials or bulk materials of similar composition, it is meant the the properties of the porous material are compared to a bulk material of similar composition to the solid part of the porous material, where the bulk material is a piece of solid material, or nearly solid material, that has dimensions in the millimetre range or larger. For the case where the porous material is comprised of a coating of material applied to an essentially inert substrate, the bulk material is of similar composition to the composition of the coating material, i.e. the composition of the inert substrate is not relevant.

Where reference is made to a comparison or ratio of properties referenced to the properties of comparable thin-film materials or thin-film materials of similar composition, it is meant that the properties of the porous material are compared to a thin-film of solid material of similar composition to the solid part of the porous material, deposited onto an essentially flat, solid substrate. For the case where the porous material is comprised of a coating of material applied to an essentially inert substrate, the thin-film material is of similar composition to the composition of the coating material, i.e. the composition of the inert substrate is not relevant, and the thickness of the thin-film material is similar to the coating thickness.

The porous substrate used in the present invention is suitably a porous membrane. Such porous membranes include polymeric filter membranes, filter papers, track-etched membranes, sintered ceramic membranes, other ceramic membranes, porous metallic membranes, aerogel membranes or xerogel membranes. The membranes may, have a wide range of thicknesses, from the micrometre range to the millimetre range.

### BRIEF DESCRIPTION OF THE DRAWINGS

FIG. 1 shows a scanning electron micrograph of coated cellulose acetate filter membrane material from example 1;

FIG. 2 shows a scanning electron micrograph of coated cellulose nitrate material from example 2;

FIG. 3 shows a scanning electron micrograph of uncoated cellulose nitrate filter membrane; and

FIG. 4. Transmission electron micrograph showing nanolayers in coating from example 4.

In order to better understand embodiments of the present invention, the following examples are provided.

### EXAMPLES

### Example 1

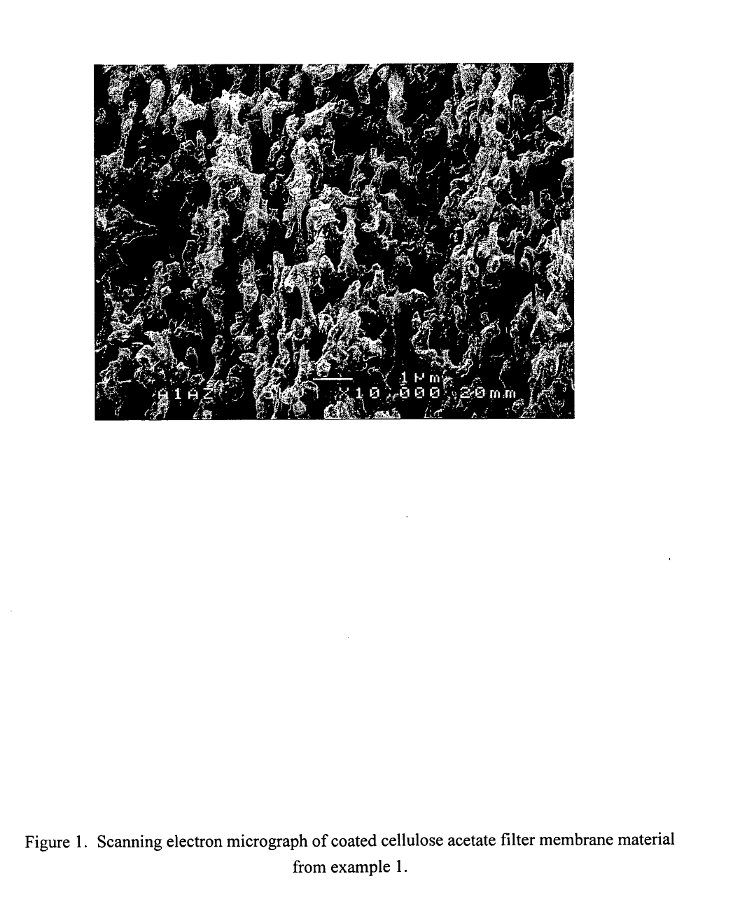

Cellulose acetate filter membrane material, thickness ˜127 μm, was coated with nominally 1% Al-doped ZnO using ALD. A nucleating coating of Al₂O₃ was first put down on the material. The target coating thickness was ˜12 nm. From subsequent weight measurements, the volume fraction of coating was estimated to be ˜6%. The surface area of this membrane material measured using BET method was 10 m²/g. The specified volume fraction of solid in these membranes was ˜34%. Using these figures, and assuming a flat surface, a 12 nm thick coating of zinc oxide should give a volume fraction of coating of around 5.5%. This is close to the measured 6%. FIG. 1 shows a scanning electron micrograph of a cross-section (fracture surface) of the coated material. From transmission electron microscopy the thickness of the coating was estimated to be very close to the target thickness.

### Example 2

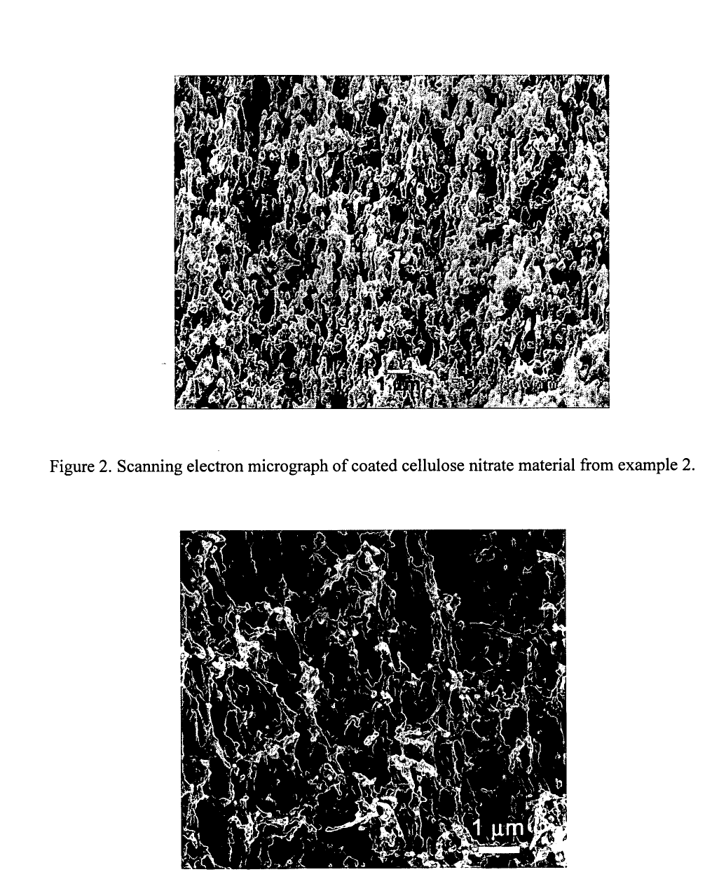

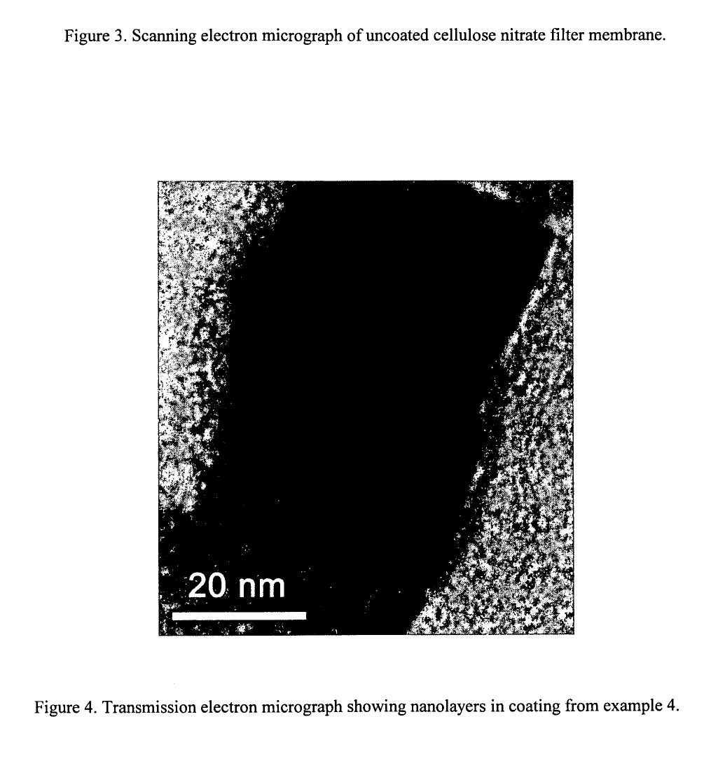

A cellulose nitrate filter membrane material with similar thickness, surface area and volume fraction solid was used in place of the cellulose acetate material in example 1. It was coated with 1% Al-doped ZnO using flow-through ALD. The target thickness was ˜12 nm. Using these figures, and assuming a flat surface, a 12 nm thick coating of zinc oxide should give a volume fraction of coating of around 5.5%. From subsequent weight measurements, the volume fraction of coating was estimated to be ˜6.8%. FIG. 2 shows a scanning electron micrograph of a cross-section (fracture surface) of the coated material. FIG. 3 shows a scanning electron micrograph of the original, uncoated porous membrane. Clearly the pore architecture has remained very similar. From transmission electron microscopy the thickness of the coating was estimated to be very close to the target thickness.

### Example 3

Cellulose acetate filter membrane as in example 1 was coated with 40 nm of nominally 2% Al-doped ZnO. A 1 nm thick Al₂O₃ nucleating layer was first deposited. ALD was carried out at 100° C. The as deposited conductivity at room temperature (RT) was 0.82 S/cm. The equivalent solid conductivity was about 4.1 S/cm. After heat treatment, the polymer was removed and the RT conductivity increased to 37 S/cm. The equivalent solid conductivity was about 185 S/cm, i.e. the volume fraction of deposited solid was about 20%. The thermal conductivity of the material after heat treatment, measured under vacuum at RT, was 0.096 W/m/K. The ratio of electrical conductivity to thermal conductivity was 38,400 SK/W. For comparison, in an Al-doped. ZnO material with excellent thermoelectric performance, this ratio is only ˜4,450 at RT.

### Example 4

ALD coating was carried out on cellulose acetate filter membrane as in example 3, except ALD was carried out at 140° C. The as-deposited RT conductivity was 28.6 S/cm. The equivalent solid conductivity was about 143 S/cm, i.e. the volume fraction of deposited solid was ˜20%. The RT thermal conductivity was 0.18 W/m/K. The ratio of electrical conductivity to thermal conductivity was 15,000 SK/W. The material was heat-treated and the polymer removed. The RT conductivity was then 47.6 S/cm. The equivalent solid conductivity was about 238 S/cm.

### Example 5

ALD coating was carried out as per example 2, however the coating thickness was 20 nm, and a thinner nucleating layer was used. The as-deposited RT conductivity was 0.013 S/cm. The equivalent solid conductivity was about 0.13 S/cm, i.e. the volume fraction of deposited solid was ˜10%. Heat treatment removed the polymer and increased the RT conductivity to 6.7 S/cm. The equivalent solid conductivity was about 33.5 S/cm.

### Example 6

ALD coating was carried out as per example 2, except a 1 nm thick Al₂O₃ cap was placed over the coating. The as-deposited RT conductivity was 34.5 S/cm. The equivalent solid conductivity was about 172.5 S/cm, i.e. the volume fraction of deposited solid was ˜20%. Heat treatment removed the polymer and increased the RT conductivity to 55.6 S/cm. The equivalent solid conductivity was about 278 S/cm.

### Example 7

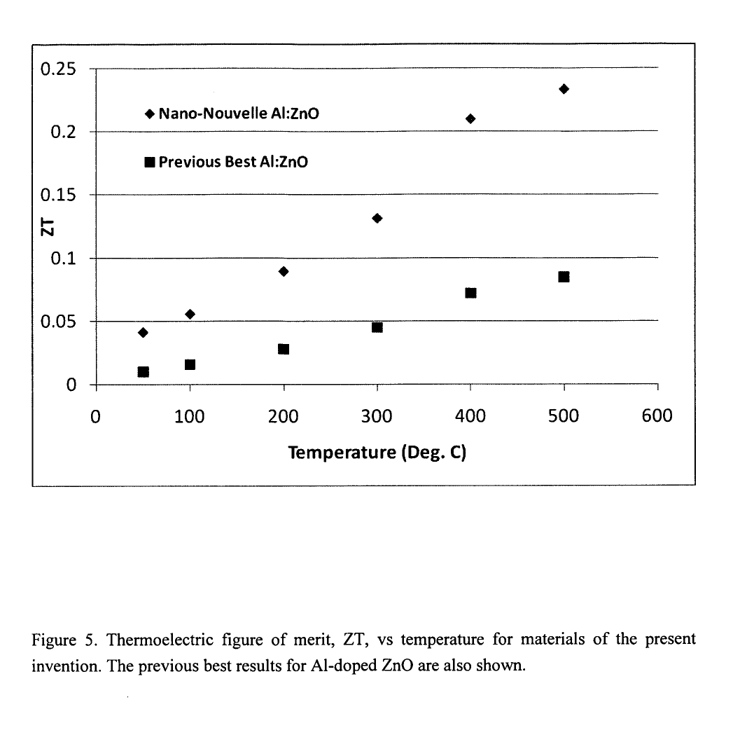

ALD coating was carried out on the same cellulose acetate filter membrane material as example 1. A 40 nm thick coating, comprising nanolayers, of Al₂O₃ and ZnO, was deposited by ALD. TEM showed the successful deposition of the nanolayers (FIG. 4). Heat treatment removed the polymer. The RT conductivity after heat treatment was ˜3 S/cm. The equivalent solid conductivity was about 15 S/cm.

### Example 8

An ALD coating, nominally 2% Al-doped ZnO, of thickness ˜80 nm, was applied to a cellulose acetate filter membrane of nominal pore size 400 nm. A nucleating layer of Al₂O₃ was applied prior to the Al-doped ZnO. The volume fraction of solid was determined to be ˜21%. The, material was subjected to a rapid thermal anneal of a few seconds at about 800° C., under a Ar/H₂ atmosphere. The electrical conductivity, thermal conductivity and Seebeck coefficients were measured from room temperature to 500° C. These combine to give a thermoelectric figure of merit, ZT. A plot of ZT vs temperature for this material is shown in FIG. 5. Also in this figure are the previous best results for Al-doped zinc oxide (“High Thermoelectric Performance of Dually Doped ZnO Ceramics”, Ohtaki et al., Journal of ELECTRONIC MATERIALS, Vol. 38, No. 7, 2009”. It can be seen the material achieves ZT ˜0.24 at 500° C., which is nearly three times better performance than the previous best for this material. The electrical conductivity at 200° C. was 117.3 S/cm, giving an equivalent solid conductivity of 558 S/cm. This compares to the room temperature conductivity of 2% Al-doped ZnO obtained by Ohtaki et al for bulk material of ˜2000 S/cm. Typical values for thin films of similar material at similar thicknesses to the coating thickness are less than 1000 S/cm. The thermal conductivity at 200° C. was 0.1655 W/m/K. The equivalent thermal conductivity is 0.79 W/m/K. This compares to about 17.5 W/m/K from Ohtaki et al. The ratio of electrical conductivity to thermal conductivity was therefore 70,869 SK/W. This compares to about 4,450 SK/W by Ohtaki et al at room temperature. This material was subjected to a compressive load of about 8.3 MPa and no damage was observed. The phonon thermal conductivities for this material between room temperature and 500° C. were estimated and ranged between ˜0.01 and ˜0.04 W/m/K, giving equivalent values of between ˜0.048 and 0.19. These values compare to estimated values from the data of Ohtaki et al of ˜38 at room temperature to ˜9.6 at 500° C. The ratios of phonon thermal conductivity to electronic thermal conductivity were estimated as between ˜0.05 and ˜0.3. This compares to this ratio from the data of Ohtaki et al, being ˜26 at room temperature to ˜5.1 at 500° C.

### Example 9

The same material as prepared in example 8 was prepared without any heat treatment. This material was exposed to acetone. After 1 day immersion, the material appeared unaffected.

### Example 10

A cellulose acetate filter, nominal pore size 200 nm, was coated with a ˜20 nm thick coating of Al-doped zinc oxide. This material was immersed in acetone and appeared unaffected.

### Comparative Example 1

An uncoated cellulose acetate membrane material of the same type as used in examples 9 and 10 was exposed to acetone and immediately shrivelled up, grossly deforming and softening severely. After several hours it was completely dissolved.

### Example 11

A cellulose acetate filter membrane was coated with ˜30 nm of Al₂O₃ using ALD. This material was exposed to flowing nitrogen gas at 200° C. for 4 hours. Following this, the material had little deformation.

### Comparative Example 2

An uncoated cellulose acetate filter membrane of identical type to example 11 was also exposed to flowing nitrogen gas at 200° C. for 4 hours. Following this, the material had extensive deformation.

1.-44. (canceled)

45. A porous material comprising a porous membrane substrate coated with a thin, uniform coating of a different material wherein the coating imparts high conductivity to the membrane and wherein the porous material has a volume fraction of solid of less than 50%, or less than 40%, or less than 30%, or less than 25% or less than 5.5%.

46. A porous material as claimed in claim 45 wherein the porous material is formed by coating the porous substrate and treating the coated material to remove the substrate and leave the porous material.

47. A porous material comprising a porous membrane substrate coated with a thin, uniform coating of a different material wherein the coating imparts high conductivity to the membrane and wherein the porous material has a volume fraction of coating of less than 50%, or less than 40%, or less than 30%, or less than 25% or less than 5.5%.

48. A porous material as claimed in claim 45 wherein the coating extends all through the porous material.

49. A porous material as claimed in claim 45 wherein an equivalent solid conductivity of the membrane ranges from ˜0.05 S/cm to 1500 S/cm, preferably 10 S/cm to 1500 S/cm, more preferably 100 S/cm to 1500 S/cm.

50. A porous material as claimed in claim 45 wherein an equivalent conductivity of the porous material is at least ˜0.016%, or at least ˜¼ or at least ˜½ that obtained for thin films of similar composition and thickness deposited on solid substrates, preferably the equivalent conductivity of the porous material comparable to conductivity values obtained for thin films of similar composition and thickness deposited on solid substrates, or even superior.

51. A porous material as claimed in claim 45 wherein the equivalent conductivity of the porous material is ˜0.0065% or greater than that obtained for bulk materials of similar composition, or ˜ 1/50^{th} or greater than that obtained for bulk materials of similar composition, or ˜ 1/20^{th} or greater than that obtained for bulk materials of similar composition, or ˜ 1/10^{th} or greater than that obtained for bulk materials of similar composition, or ˜⅕^{th} or greater than that obtained for bulk materials of similar composition, or ½ or greater than that obtained for bulk materials of similar composition, or even comparable to or superior to that obtained for bulk materials of similar composition.

52. A porous material as claimed in claim 45 wherein the coating comprises a transparent conducting oxide such as doped zinc oxide, doped tin oxide, doped indium oxide, doped titanium oxide, or variants thereof.

53. A porous material as claimed in claim 45 wherein the equivalent solid conductivity of the porous material ranges from ˜0.05 S/cm to 1500 S/cm, or 10 S/cm to 1500 S/cm or 100 S/cm to 1500 S/cm.

54. A porous material as claimed in claim 45 wherein the coating has a thickness of less than 10 nm to 200 nm, preferably from ˜10 nm to ˜200 nm, more suitably from ˜10 nm to ˜100 nm, even more suitably from ˜10 nm to ˜50 nm, most suitably from ˜10 nm to ˜40 nm, or ˜10 nm, or ˜20 nm thick, or ˜40 nm thick coatings.

55. A porous material as claimed in claim 45 wherein the porous material has a figure of merit, ZT, that is comparable or higher than ZT values for bulk materials of similar composition.

56. A porous material characterized in that the porous material has a figure of merit, ZT, that is comparable or higher than ZT values for bulk materials of similar composition and wherein the porous material has a volume fractions of solid (v_{f} solid) of less than 50% v_{f} solid, or less than 40% v_{f} solid, or less than 30% v_{f} solid, or less than 20% v_{f} solid or less than 5.5% v_{f} solid.

57. A porous material as claimed in claim 56 wherein the porous material has a figure of merit, ZT, greater than 1.2 times higher than comparable bulk materials, or greater than 2 times higher than comparable bulk materials, or greater than 3 times higher than comparable bulk materials, or greater than 5 times higher than comparable bulk materials, or greater than 10×higher than comparable bulk materials.

58. A porous material having a thermoelectric figure of merit in excess of 0.1, or from 0.1 to 5, or from 0.3 to 5, or from 0.3 to 4, or from 0.3 to 3, or from 0.3 to 2, or from 0.3 to 1.5 and wherein the porous material has a volume fractions of solid (v_{f} solid) of less than 50% v_{f} solid, or less than 40% v_{f} solid, or less than 30% v_{f} solid, or less than 20% v_{f} solid.

59. A porous material as claimed in claim 45 wherein a porous substrate is coated with a material selected from oxides including zinc oxide, titanium oxide, tin oxide, indium oxide, indium tin oxide, gallium oxide, tungsten oxide, cobalt oxides, complex oxides such as strontium titanates and rare earthtype titanates, and perovskite-type oxides and mixtures of these, nitrides including aluminium nitride and gallium nitride, titanium nitride, silicon nitride and mixtures of these, metals including copper, tin, nickel, iron, aluminium, titanium, cobalt, zinc, manganese, silver, gold, and alloys of these, thermoelectric materials including thermoelectric oxides such as zinc-based oxides, cobalt-based oxides, titanium-based oxides including perovskite type oxides, bismuth tellurides, antimony tellurides, lead tellurides, other tellurides and mixed tellurides, Zintl compounds, Huessler materials, skutteridites, silicides, antimonides, and mixtures or compounds based on these, for example so-called TAGS and LAST -type materials, semiconductors, including silicon, germanium, silicon carbides, boron carbides, cadmium telluride, cadmium selenide, indium phosphide, copper indium gallium based semiconductors, and mixtures of two or more thereof.

60. A porous material as claimed claim 45 wherein a porous substrate is coated with a material and the coating is doped with dopants to become conductive.

61. A porous membrane material as claimed in claim 60 wherein doping is intrinsic or doping is extrinsic.

62. A porous membrane material as claimed in claim 61 wherein intrinsic doping results in inclusion of intrinsic dopants selected from oxygen vacancies, metallic interstitials, hydrogen, oxygen interstitialsor metallic vacancies or a combination of two or more thereof.

63. A porous material as claimed in claim 60 wherein the material is heat treated or annealed after deposition to activate the dopants.

64. A porous membrane material as claimed in claim 45 wherein a porous substrate is coated with a material and the coating applied to the substrate has a thickness that falls within the range of from ˜10 nm to ˜200 nm, more suitably from ˜10 nm to ˜100nm, even more suitably from ˜10 nm to ˜50 nm, most suitably from ˜10 nm to ˜40 nm. ˜10 nm, or ˜20 nm thick, or ˜40 nm thick coatings.

65. A porous material as claimed in claim 45 wherein the material is post-treated to add additional functionality.

66. A porous material as claimed in claim 45 wherein nanoparticles of material are applied to the surface.

67. A porous material as claimed in claim 45 wherein a porous substrate is coated with a material and the porous substrate is removed after application of the coating.

68. A porous material as claimed in claim 67 wherein the porous substrate is removed by application of heat.

69. A porous material as claimed in claim 67 wherein the porous substrate is removed without causing significant shrinkage.

70. A porous material as claimed in claim 69 wherein the thickness of the material after removal of the scaffold is within 10% of the original thickness, preferably within 5%, more preferably within 2%.

71. A porous material as claimed in claim 45 wherein a porous substrate is coated with a material and the coating is comprised of nanolayers of material.

72. A porous material as claimed in claim 71 wherein the coating comprises a plurality of nanolayers.

73. A porous material as claimed in claim 45 wherein the porous substrate is a polymer membrane.

74. A porous material as claimed in claim 45 wherein the porous material has a ratio of compressive strength (measured in Mpa) to volume fraction of solids (measured as volume fraction) of greater than 5 Mpa/v_{f}, or greater than 10 MPa/v_{f}, or greater than 50 MPa/v_{f}, or greater than 100 MPa/v_{f}.

75. A porous material as claimed in claim 45 wherein a thin layer of solid material is placed on top of the porous material, to provide a contacting surface.

76. A porous material having a ratio of electrical conductivity to thermal conductivity that is significantly higher than the ratio of electrical conductivity to thermal conductivity for bulk materials of similar composition and wherein the porous material has a volume fractions of solid (v_{f} solid) of less than 50% v_{f} solid, or less than 40% v_{f} solid, or less than 30% v_{f} solid, or less than 20% v_{f} solid or less than 5.5% v_{f} solid.

77. A porous material as claimed in claim 76 wherein the ratio of electrical conductivity to thermal conductivity of the porous material is at least 2 times higher the ratio of electrical conductivity to thermal conductivity for bulk material of similar composition, or 2 to 5 times higher, or 2 to 10 times higher or up to 20 times higher than reported for bulk materials of similar composition.

78. A porous material having a ratio of electrical conductivity to thermal conductivity in excess of 10,000 SK/W, for example, from 10,000 to 200,000 SK/W, or from 15,000 to 100,000 SK/W, or from 20,000 to 50,000 SK/W, as determined at a temperature of from ˜15° C. to ˜35° C.

79. A porous material having a phonon thermal conductivity of less than 0.6 W/m/K, or less than 0.5, or less than 0.3, or less than 0.2.

80. A porous material having a phonon conductivity that is comparable to the phonon conductivity for bulk materials of similar composition.

81. A porous material as claimed in claim 80 wherein the phonon conductivity is about ½ of the phonon conductivity for bulk materials of similar composition, or about ¼ of the phonon conductivity for bulk materials of similar composition, or about 1/10^{th} of the phonon conductivity for bulk materials of similar composition, or about 1/20^{th} of the phonon conductivity for bulk materials of similar composition or about 1/50^{th} of the phonon conductivity for bulk materials of similar composition.

82. A porous material as claimed in claim 78 wherein the porous material has a volume fractions of solid (v_{f} solid) of less than 50% v_{f} solid, or less than 40% v_{f} solid, or less than 30% v_{f} solid, or less than 20% v_{f} solid or less than 5.5% v_{f} solid.

83. A method for forming a porous material as claimed in claim 45 comprising providing a porous substrate material and applying a thin uniform coating to the porous structure material.

84. A method as claimed in claim 83 wherein the porous material is made by applying a thin, uniform coating to the porous substrate material and subsequently removing the porous substrate material.

85. A method as claimed in claim 84 wherein the porous substrate material is removed by heat treatment or by chemical treatment

86. A method as claimed in claim 85 wherein the heat treatment or chemical treatment removes the substrate material without unduly affecting the coating material.

87. A method as claimed in claim 83 wherein the thin uniform coating is applied using atomic layer deposition (ALD).

88. A method as claimed in claim 83 wherein the coating applied to the substrate has a thickness that falls within the range of from less than 10 nm to ˜200 nm, more suitably from ˜10 nm to ˜100 nm, even more suitably from ˜10 nm to ˜50 nm, most suitably from ˜10 nm to ˜40 nm.˜10 nm, or ˜20 nm thick, or ˜40 nm thick coatings.
